(19) United States
(12) Patent Application Publication
(10) Pub. No.: US 2003/0204806 A1
(43) Pub. Date: Oct. 30, 2003

(54) Signal transmission system

(75) Inventors: Masashi Hisada, Kanagawa (JP); Kazuhiro Sakai, Kanagawa (JP); Tsutomu Hamada, Kanagawa (JP); Takeshi Kamimura, Kanagawa (JP)

Correspondence Address: OLIFF & BERRIDGE, PLC, P.O. BOX 19928, ALEXANDRIA, VA, 22320, US

(73) Assignee: Fuji Xerox Co., Ltd., Tokyo (JP)

(21) Appl. No.: 10/395,394

(22) Filed: Mar. 25, 2003

(30) Foreign Application Priority Data
Apr. 26, 2002 (JP) 2002-126932

(51) Int. Cl. H03M 13/00

(52) U.S. Cl. 714/758

(57) ABSTRACT

A signal transmission system has a transmission apparatus, a reception apparatus, and a transmission path. In the transmission apparatus, after signal sequences are coded by 8B10B encoders so as to attain DC balance, an error correction code is added to the coded signal sequences by an ECC adder, and the signal sequences are then transmitted. In the reception apparatus, error correction is conducted on the received signal sequences by error correction sections, and the coded signal sequences are then decoded by the 10B8B decoders so as to attain DC balance.

### CROSS REFERENCE OF RELATED APPLICATION

This application is based on and claims priority under 35 U.S.C. §119 with respect to Japanese Patent Application No. 2002-126932 filed on Apr. 26, 2002, the entire content of which is incorporated herein by reference.

### BACKGROUND OF THE INVENTION

1. Field of the Invention

The present invention relates to a signal transmission system, and more particularly to a signal transmission system in which error corrections are conducted on a signal sequence with using an error correction code.

2. Description of the Related Art

As a system for processing an error of a parallel signal due to a fault of a transmission path, for example, JP-A-9-64853 discloses a technique in which a spare transmission path is disposed in addition to a regular transmission path, and an n-bit signal as a whole is not caused to become an error signal by a fault in one transmission path. In some computers and transmission process apparatuses, there is a case where transmission of parallel data is conducted by using only a currently used transmission path and no spare transmission path is disposed. In such a case, there arises a problem in that, even when a fault occurs in at least one transmission path (channel) for one bit of parallel-transmitted n-bit data, an n-bit signal which as the whole of the n bits has a meaning is caused to become error data. This circumstance similarly arises also in parallel transmission of light signals. When deterioration or the like occurs in one of light emitting elements disposed in the transmission side of optical lines for respective bits and light receiving elements disposed in the reception side, for example, n-bit parallel data which is transmitted through an n number of parallel optical lines (channels) may be adversely affected.

### SUMMARY OF THE INVENTION

It is an object of the invention to provide a signal transmission system in which an error occurring in one of plural channels through which plural signal sequences are respectively transmitted can be suitably corrected.

To achieve the above object, according to one aspect of the invention, there is provided a signal transmission system which transmits plural signal sequences through corresponding plural channels, wherein errors on the plural signal sequences are collectively corrected according to an error correction code.

Preferably, a channel for the error correction code is additionally disposed. The error correction code is preferably added after the signal sequences are coded so as to attain DC balance. A bit which is obtained by inverting the error correction code may be added to the error correction code. A dummy bit may be added to the error correction code to match a bit number of parallel transmission with a bit number of serial transmission.

According to another aspect of the invention, there is provided a transmission apparatus which transmits plural signal sequences through corresponding plural channels, wherein, after the signal sequences are coded so as to attain DC balance, an error correction code is added to the coded signal sequences, and the resulting coded signal sequences are then transmitted.

According to still another aspect of the invention, there is provided a reception apparatus which receives plural signal sequences to which an error correction code is added, through corresponding plural channels, wherein, after error correction is conducted on the received signal sequences, the signal sequences which are coded so as to attain DC balance are decoded.

According to the configuration, random errors produced in one of plural channels through which plural signal sequences are respectively transmitted can be suitably corrected.

### BRIEF DESCRIPTION OF THE DRAWINGS

FIG. 1 is a diagram showing an embodiment of the signal transmission system of the invention.

FIGS. 2A to 2H are diagrams illustrating an example of error correction in the signal transmission system of the invention.

### DETAILED DESCRIPTION OF THE PREFERRED EMBODIMENTS

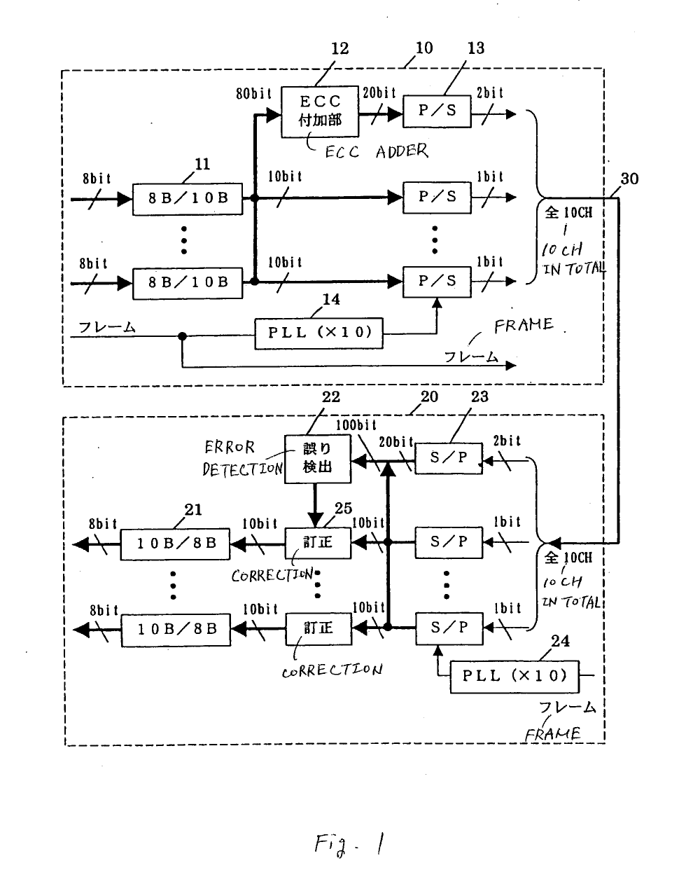

FIG. 1 is a diagram showing a signal transmission system according to an embodiment of the invention. As shown in the figure, the system includes a transmission apparatus 10, a reception apparatus 20, and a transmission path 30 through which the apparatuses are connected to each other. Plural signal sequences are transmitted through corresponding plural channels, respectively. Error corrections on the plural signal sequences are collectively conducted according to an error correction code as described later.

The transmission apparatus 10 has 8B10B encoders 11 which perform a coding process so that 8-bit data is sent in the form of 10-bit data; an ECC adder 12 which adds an error correction code for automatically correcting a bit error; P/S converters 13 which convert a parallel signal to a serial signal; and a PLL 14 which multiplies a frame signal that is a synchronization signal, by 10 to produce a high-speed clock signal for a serial signal.

As described above, in the embodiment, the transmission apparatus 10 is configured so as to transmit 64-bit data through eight channels. Therefore, a parallel signal in which 8 bits are allocated to each channel is used. The 8B10B coding process is applied to the data by the 8B10B encoder 11. The 8B10B coding process has advantages that the state of “0” or “1” does not continue, and that excellent DC balance is attained. In the 8B10B coding process, five or more identical bit data do not continue. With respect to DC balance, data of a certain length is coded so that “0” and “1” are substantially equal in number to each other.

In the output of the 8B10B encoder 11, there are eight channels of 10 bits, and the total bit number is 80 bits. The ECC adder 12 adds an error correction code to the 80 bits. In the error correction code, 7 bits are used as check bits, and inverted bits and dummy bits are added to the code. In the embodiment, 20 bits are allocated to the code as described later. The addition of an error correction code will be described later in detail.

Each of the P/S converters 13 converts the 10-bit parallel signal of 8 channels which is the output of the corresponding 8B10B encoder 11, into a 1-bit serial signal according to the high-speed clock signal which is produced by the PLL 14. Similarly, the P/S converter 13 converts a parallel signal of 2 channels which is an output of the ECC adder 12, into a serial signal. In this way, serial data of 10 channels in total is transmitted into the transmission path 30.

On the other hand, the reception apparatus 20 has: 10B8B decoders 21 which decode 10-bit data to 8-bit data; an error detector 22 which detects a bit error; S/P converters 23 which convert a serial signal into a parallel signal; a PLL 24 which multiplies the frame signal that is sent from the transmission apparatus, by 10 to produce a high-speed clock signal for a serial signal; and error correction sections 25 which correct an error in data.

The reception apparatus 20 receives the serial data of 10 channels via the transmission path 30. Each of the S/P converters 23 converts serial data of the respective channel into parallel data with using the high-speed clock signal which is produced by the PLL 24. The error detector 22 detects an error in the 10-bit data of 8 channels on the basis of the error correction code. The error correction sections 25 correct the detected error. The 10B8B decoders 21 decode the 10-bit data of 8 channels which have undergone the error correction, to respective 8-bit data. The 8-bit data is further processed in a subsequent stage. The error correction will be described in detail.

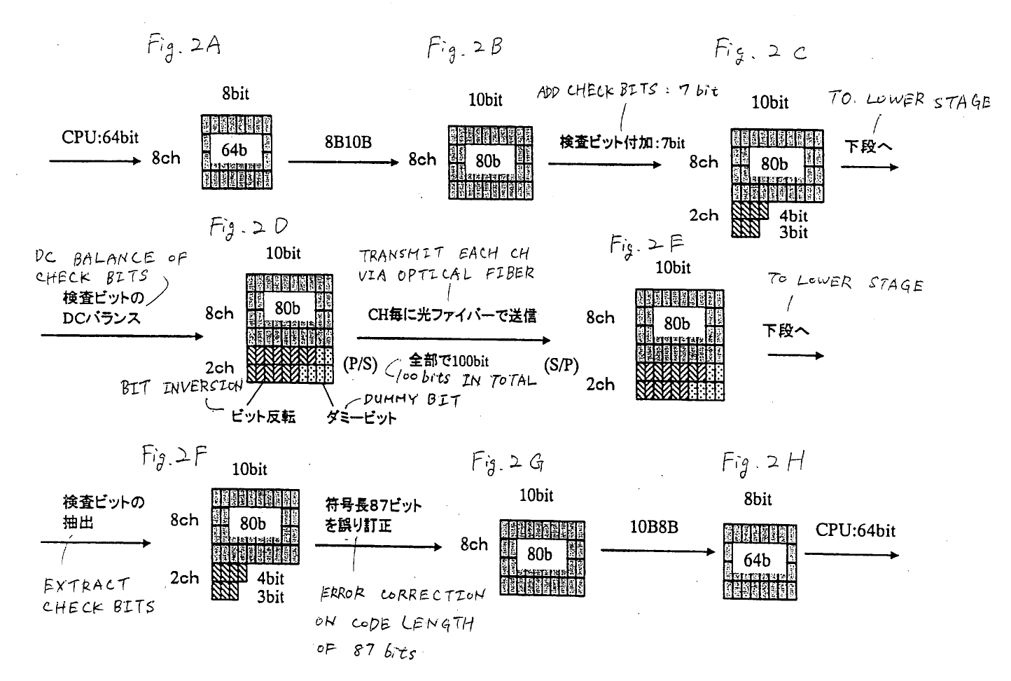

In FIGS. 2A to 2H are diagrams illustrating an example of the error correction in the signal transmission system of the invention. In a signal transmission system using a cable transmission path, it seems that a burst error hardly occurs, and it is required to configure the system so as to correct random errors. In this example, therefore, a Hamming code is used as the error correction code. When a Hamming code is used, detection of 1-bit error, and even correction of the detected error are enabled. Three parity bits (redundant bits) are added to 4 bits of data to produce a 7-bit code. These 7 bits are used as check bits.

As shown in FIG. 2A, 64 bits of the 8-bit data of 8 channels are sent from a CPU. The 64-bit data is converted into 80 bits of 10-bit data by 8 channels by the 8B10B coding process as shown in FIG. 2B. The 7 check bits are added to the 80-bit data. As shown in FIG. 2C, two channels of 4 and 3 bits are allocated to the 7 bits of check bits. In order to attain DC balance in the check bits, as shown in FIG. 2D, inverted bits of the check bits are added, and, in order to match the bit number of the parallel signal with that of the serial signal, dummy bits are added. In this example, inverted 7 bits for the check bits, and 6 dummy bits are used, so that 20 bits are allocated to the two channels. Therefore, the bits to be transmitted are configured by 80 bits of data bits and 20 bits of additional bits, that is 100 bits in total. The 100 bits of data are converted from a parallel signal into a serial signal. The converted data for each channel is transmitted from the transmission apparatus to the reception apparatus via the transmission path such as an optical fiber.

As shown in FIG. 2E, the reception apparatus converts the received serial signal into a parallel signal. Thereafter, the 4 and 3 check bits are extracted as shown in FIG. 2F. In the case where an error occurs in the 1-bit inversion, 1 or 0 may be employed. Error correction is then conducted on the code length of 87 bits to obtain 80 bits of 10-bit data by 8 channels as shown in (g) of FIG. 2. The 10-bit data is decoded to 8-bit data by a 10B8B decoding process to obtain 64 bits of 8-bit data by 8 channels as shown in FIG. 2H. The obtained data is transmitted to a CPU in the subsequent stage.

Conventionally, in the transmit side, a scheme of error correction is implemented before 8B10B coding, and, in the receive side, that of error correction is implemented after 10B8B decoding. Therefore, an error which is caused in an optical transmission path cannot be corrected.

In the invention, multiple channels are collectively subjected to error correction. Therefore, the ratio of check bits to data bits can be set to be small, so that the transmission efficiency can be improved. In the transmission side, check bits are added to data which has undergone the coding process (8B10B) for attaining DC balance, and in the reception side, the decoding process (10B8B) is conducted after error correction. Consequently, an error caused in an optical transmission path can be corrected.

According to the invention, it is possible to obtain a signal transmission system in which an error occurring in one of plural channels through which plural signal sequences are respectively transmitted can be suitably corrected.

What is claimed is:

1. A signal transmission system comprising:
a transmission apparatus;
a reception apparatus; and
a transmission path through which the transmission apparatus and the reception apparatus are connected to each other,
wherein the signal transmission system transmits plural signal sequences through corresponding plural channels,
and wherein error corrections on the plural signal sequences are collectively conducted by an error correction code.

2. A signal transmission system according to claim 1, wherein a channel for the error correction code is additionally disposed.

3. A signal transmission system according to claim 1, wherein the error correction code is added after the signal sequences are coded to attain DC balance.

4. A signal transmission system according to claim 1, wherein a bit which is obtained by inverting the error correction code is added to the error correction code.

5. A signal transmission system according to claim 1, wherein a dummy bit is added to the error correction code to match a bit number of parallel transmission with a bit number of serial transmission.

6. A transmission apparatus comprising:
an encoder for coding a signal sequence so as to attain DC balance; and
an ECC adder for adding an error correction code to the coded signal sequence,
wherein the transmission apparatus transmits plural signal sequences through corresponding plural channels.

7. A reception apparatus comprising:
an error correction section for conducting error correction of the received signal sequences; and
a decoder for decoding the signal sequences which are coded so as to attain DC balance
wherein the reception apparatus receives plural signal sequences to which an error correction code is added through corresponding plural channels.
